(19) United States
(12) Patent Application Publication
(10) Pub. No.: US 2024/0260427 A1
(43) Pub. Date: Aug. 1, 2024

(54) DISPLAY PANELS AND DISPLAY DEVICES

(71) Applicant: WUHAN CHINA STAR OPTOELECTRONICS SEMICONDUCTOR DISPLAY TECHNOLOGY CO., LTD., Wuhan (CN)

(72) Inventors: Kai HU, Wuhan (CN); Juan LIU, Wuhan (CN)

(21) Appl. No.: 18/288,683

(22) PCT Filed: Jun. 30, 2023
(86) PCT No.: PCT/CN2023/104608

§ 371 Date: Oct. 27, 2023

(30) Foreign Application Priority Data
Jan. 31, 2023 (CN) 202310099025.0

(51) Int. Cl. H10K 59/80; H10K 59/122

(52) U.S. Cl. CPC H10K 59/8792; H10K 59/122

(57) ABSTRACT

A display panel and a display device are provided, including: a substrate; multiple first electrode units; a pixel definition layer defining multiple pixel definition openings corresponding to the first electrode units; and a light-emitting layer covering the first electrode units; where each of the first electrode units includes an edge part protruded from an edge of one of the pixel definition openings corresponding to the first electrode units, the pixel definition layer includes a light-shielding function layer, an orthographic projection of the light-shielding function layer on each of the first electrode unit covers at least a portion of the edge part corresponding to the first electrode unit, and the light-shielding function layer and the light-emitting layer are arranged at intervals.

### TECHNICAL FIELD

The present disclosure relates to the field of display technologies, and more particularly, to a display panel and a display device.

### BACKGROUND

Organic light emitting diode (OLED) display panels, compared with liquid crystal display, have the advantages of being lighter and thinner, better in display effect, higher in resolution, wider in color gamut, lower in power consumption, and capable of realizing flexible displays, which make them develop rapidly in recent years. Therefore, the OLED display panel has become a preferred type of display panels for mobile terminals.

At present, in order to further reduce manufacturing costs of the OLED display panel and make the OLED display panel lighter and thinner, a framework using a black matrix (BM) and a color filter (CF) is proposed to replace a polarizer with an anti-reflective function in existing frameworks. However, an OLED display panel with this framework needs to maintain a transmittance of the CF at a high level to balance a light-emitting efficiency of the OLED display panel, which greatly reduces an anti-reflective function of the CF, further reduces an anti-reflective performance of the OLED display panel against ambient light, and generates a problem of reflection generated in an off-screen state of the display panel, and it is urgent to solve the problem.

### SUMMARY

The present disclosure provides a display panel and a display device, which can effectively improve anti-reflective performances of the display panel and the display device, and improve a problem of reflection generated in an off-screen state of the display panel.

According to a first aspect, the present disclosure provides a display panel, including: a substrate; a first electrode layer disposed on a side of the substrate, and including multiple first electrode units arranged at intervals; a pixel definition layer disposed on a side of the first electrode layer away from the substrate and defining multiple pixel definition openings corresponding to the first electrode units; a light-emitting layer disposed on a side of the pixel definition layer away from the substrate, and covering the first electrode units exposed by the pixel definition openings; and a light filter layer disposed on a side of the light-emitting layer away from the substrate and including multiple light filter units corresponding to the pixel definition openings; where each of the first electrode units includes an edge part protruded from an edge of each of the pixel definition openings corresponding to the first electrode unit, the pixel definition layer includes a light-shielding function layer, an orthographic projection of the light-shielding function layer on each of the first electrode units covers at least a portion of the edge part, and the light-shielding function layer and the light-emitting layer are arranged at intervals.

Optionally, the pixel definition layer further includes a transparent first pixel definition layer disposed on a surface of a side of the substrate facing towards the first electrode layer, where the light-shielding function layer is disposed on a surface of a side of the first pixel definition layer away from the substrate, and an orthographic projection of the first pixel definition layer on each of the first electrode units covers an edge part corresponding to the first electrode unit.

Optionally, the surface of the side of the first pixel definition layer away from the substrate is a flat surface.

Optionally, the light-emitting layer includes multiple light-emitting units respectively disposed in the pixel definition openings; a distance between the surface of the side of the first pixel definition layer away from the substrate and the substrate is a first distance, a distance between a surface of a side of each of the light-emitting units away from the substrate and the substrate is a second distance, and the first distance is smaller than or equal to the second distance; and an orthographic projection of the light-shielding function layer on each of the first electrode units covers a portion of the edge part corresponding to the first electrode unit, and a minimum distance between the light-shielding function layer and each of the pixel definition openings is larger than 0.

Optionally, the edge part includes a first part and a second part, an orthographic projection of the first part on the substrate overlaps an orthographic projection of the light-shielding function layer on the substrate, an orthographic projection of the second part on the substrate does not overlap the orthographic projection of the light-shielding function layer on the substrate, and a width of the first part is larger than or equal to a width of the second part.

Optionally, the pixel definition layer further includes a transparent second pixel definition layer disposed on a surface of a side of the light-shielding function layer away from the substrate, where an orthographic projection of the second pixel definition layer on the light-shielding function layer covers the light-shielding function layer.

Optionally, the light-emitting layer includes multiple light-emitting units respectively disposed in the pixel definition openings; a distance between the surface of the side of the first pixel definition layer away from the substrate and the substrate is a first distance, a distance between the surface of the side of each of the light-emitting units away from the substrate and the substrate is a second distance, and the first distance is larger than the second distance; and an orthographic projection of the light-shielding function layer on each of the first electrode units covers the at least a portion of the edge part corresponding to first electrode unit, and a minimum distance between the light-shielding function layer and each of the pixel definition openings is equal to 0.

Optionally, the light-shielding function layer includes multiple light holes, and an orthographic projection of each of the light filter units on the light-shielding function layer cover respective one of the light holes.

Optionally, the multiple light filter units include a red light filter unit, a blue light filter unit and a green light filter unit, and a transmittance of each of the light filter units for light with a color corresponding to the light filter unit is larger than or equal to 43%.

According to a second aspect, the present disclosure provides a display device, including a housing and the display panel according to any one of the foregoings, where the housing defines an accommodating space in which the display panel is disposed.

### Beneficial Effect

The present disclosure provides a display panel and a display device, the display panel includes: a substrate; a first electrode layer disposed on a side of the substrate, and including multiple first electrode units arranged at intervals; a pixel definition layer disposed on a side of the first electrode layer away from the substrate and defining multiple pixel definition openings corresponding to the first electrode units; a light-emitting layer disposed on a side of the pixel definition layer away from the substrate, and covering the first electrode units exposed by the pixel definition openings; and a light filter layer disposed on a side of the light-emitting layer away from the substrate and including multiple light filter units corresponding to the pixel definition openings; where each of the first electrode units includes an edge part protruded from an edge of each of the pixel definition openings corresponding to the first electrode unit, the pixel definition layer includes a light-shielding function layer, an orthographic projection of the light-shielding function layer on each of the first electrode units covers at least a portion of the edge part, and the light-shielding function layer and the light-emitting layer are arranged at intervals. According to the display panel and the display device provided by the present disclosure, since the pixel definition layer includes the light-shielding function layer, and the orthographic projection of the light-shielding function layer on the first electrode unit covers the at least a portion of the edge part, the pixel definition layer may absorb reflected light generated by external ambient light on the edge part, so as to effectively improve anti-reflective performances of the display panel and the display device, and improve a problem of reflection generated in an off-screen state of the display panel.

### BRIEF DESCRIPTION OF THE DRAWINGS

In order to illustrate the technical solutions in the embodiments of the present disclosure clearly, the accompanying drawings involved in the description of the embodiments are described briefly below. It will be apparent that the accompanying drawings in the following description are merely some of the embodiments of the present disclosure, and based on these drawings, other drawings may be made by those skilled in the art without involving any inventive effort.

FIG. 1 illustrates a schematic structural diagram of a display panel according to an embodiment 1 of the present disclosure.

FIG. 2 illustrates a schematic structural diagram of a display panel according to an embodiment 2 of the present disclosure.

### LIST OF REFERENCE NUMBERS

substrate 110; first electrode layer 120; first electrode unit 121; edge part 1211; first part 01; second part 02; pixel definition layer 130; pixel definition opening 1301; first pixel definition layer 131; light-shielding function layer 132; second pixel definition layer 133; light-emitting layer 140; light-emitting unit 141; second electrode layer 150; encapsulation layer 160; first encapsulation layer 161; second encapsulation layer 162; third encapsulation layer 163; touch function layer 170; first touch insulation layer 171; first touch electrode layer 172; second touch insulation layer 173; second touch electrode layer 174; black matrix 180; light filter layer 190; light filter unit 191; passivation layer 200; optical adhesive layer 210; protective layer 220.

### DETAILED DESCRIPTION OF THE EMBODIMENTS

Technical solutions of embodiments of the present disclosure will be described below clearly and fully, in connection with accompanying drawings. Obviously, the described embodiments are merely some of the embodiments of the present disclosure, not all of them. Based on the embodiments of the present disclosure, all other embodiments obtained by those skilled in the art without involving any inventive effort fall within a scope of protection of the present disclosure. Moreover, it should be understood that the specific embodiments described here are only used to describe and explain the present disclosure, and are not used to limit the present disclosure. In the present disclosure, without any explanation to the contrary, directional terms used herein such as “upper” and “lower” usually refer to the upper and lower positions of a device in an actual use or working state, specifically the direction of the figures of the accompanying drawings, and terms “inner” and “outer” refer to a profile of the device.

The following disclosure provides many different embodiments or examples for implementing different structures of the present disclosure. In order to simplify the present disclosure, the following will describe components and settings of specific examples. Obviously, they are merely examples and are not intended to limit the present disclosure. Moreover, the present disclosure may repeat reference numbers and/or reference letters in different examples, a purpose of this repetition is to simplify and clarify, and it does not in itself indicate that relationship between various discussed embodiments and/or settings. Furthermore, the present disclosure provides various examples of specific processes and materials, those skilled in the art can also realize applications of other processes and/or uses of other materials. The following are described in detail respectively, it is to be noted that the order in which the following embodiments are described is not intended to limit the preferred order of the embodiments.

### Embodiment 1

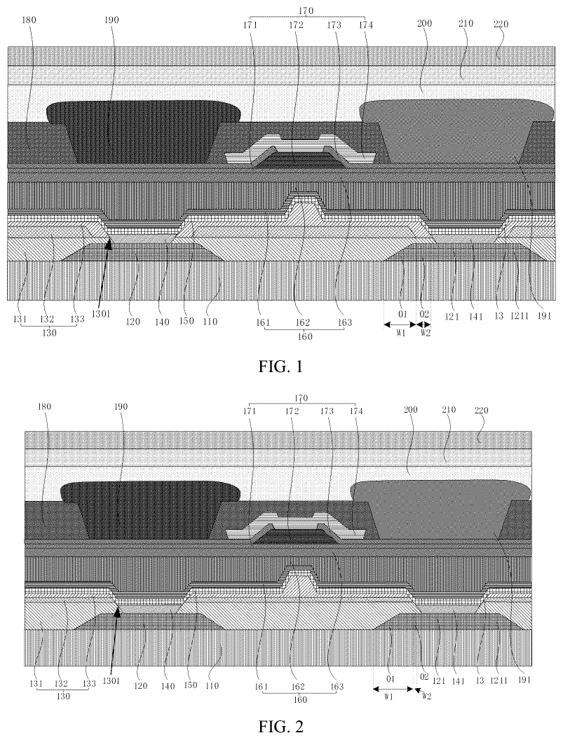

According to a first aspect, the present disclosure provides a display panel. Specifically, FIG. 1 illustrates a schematic structural diagram of a display panel according to the embodiment 1 of the present disclosure. As shown in FIG. 1, the display panel includes a substrate 110, a first electrode layer 120, a pixel definition layer 130, a light-emitting layer 140 and a light filter layer 190, the first electrode layer 120 is disposed on a side of the substrate 110, and includes multiple first electrode units 121 arranged at intervals; the pixel definition layer 130 is disposed on a side of the first electrode layer 120 away from the substrate 110, and defines multiple pixel definition openings 1301, and the pixel definition openings 1301 are disposed correspondingly to the first electrode units 121; the light-emitting layer 140 is disposed on a side of the pixel definition layer 130 away from the substrate 110, and covers parts of the first electrode units 121 exposed by the pixel definition openings 1301; the light filter layer 190 is disposed on a side of the light-emitting layer 140 away from the substrate 110, and includes multiple light filter units 191, and the light filter units 191 are disposed correspondingly to the pixel definition openings 1301; and each of the first electrode units 121 includes an edge part 1211 protruded from an edge of each of the light-emitting units 141, the pixel definition layer 130 includes a light-shielding function layer 132, an orthographic projection of the light-shielding function layer 132 on each of the first electrode units 121 covers at least part of the edge part 1211, and the light-shielding function layer 132 and the light-emitting layer 140 are arranged at intervals.

According to the display panel provided in the present disclosure, since the pixel definition layer 130 includes the light-shielding function layer 132, and the orthographic projection of the light-shielding function layer 132 on each of the first electrode units 121 covers at least part of the edge part 1211, the pixel definition layer 130 may absorb reflected light generated by external ambient light on the edge part 1211, so as to effectively improve anti-reflective performances of the display panel and a display device, and improve a problem of reflection generated in an off-screen state of the display panel.

Further, the light-shielding function layer 132 and the light-emitting layer 140 are arranged at intervals, which can effectively avoid a problem of decreased reliability of the light-emitting layer 140 caused by unstable chemical properties of the shading functional layer 132, improve stability and lifespan of the display panel, and expand a material selection range of the light-shielding function layer 132, so as to reduce manufacturing costs.

Specifically, the light-shielding function layer 132 includes a base material and a shading material with a shading property, the light-shielding function layer 132 and the light-emitting layer 140 are arranged at intervals, which can effectively avoid a problem of reduced reliability of the light-emitting layer 140 caused by a contact between the shading material and the light-emitting layer 140, and greatly improve a freedom of material selection of the shading material.

In some embodiments of the present disclosure, the pixel definition layer 130 further includes a transparent first pixel definition layer 131, and the first pixel definition layer 131 is disposed on a surface of a side of the substrate 110 facing towards the first electrode layer 120, the light-shielding function layer 132 is disposed on a surface of a side of the first pixel definition layer 131 away from the substrate 110, and an orthographic projection of the first pixel definition layer 131 on each of the first electrode units 121 covers the edge part 1211.

According to the display panel provided in the present disclosure, forming materials of the transparent first pixel definition layer 131 and the light-shielding function layer 132 are different. For example, the base material of the light-shielding function layer 132 is the same as a base material of the transparent first pixel definition layer 131, the shading material of the light-shielding function layer 132 includes inorganic light absorbing particles, conversely, the transparent first pixel definition layer 131 does not include inorganic light absorbing particles. When the light-shielding function layer 132 including the inorganic light absorbing particles is directly disposed on the first electrode units 121, a residual problem is easily to generate in a process of peeling off the light-shielding function layer 132 after patterning. In the present disclosure, the light-shielding function layer 132 is disposed on the surface of the side of the first pixel definition layer 131 away from the substrate 110, and the orthographic projection of the first pixel definition layer 131 on each of the first electrode units 121 covers the edge part 1211, so as to avoid the residual problem, and improve a film-forming quality of the light-shielding function layer 132.

In some embodiments of the present disclosure, the surface of the side of the first pixel definition layer 131 away from the substrate 110 is a flat surface.

According to the display panel provided in the present disclosure, since the surface of the side of the first pixel definition layer 131 away from the substrate 110 is the flat surface, a good film-forming platform for the light-shielding function layer 132 is provided, thereby further improving the film-forming quality of the light-shielding function layer 132, and ensuring the shading performance of the light-shielding function layer 132.

In some embodiments of the present disclosure, the light-emitting layer 140 includes multiple light-emitting units 141, and the light-emitting units 141 are disposed in the pixel definition openings 1301; a distance between the surface of the side of the first pixel definition layer 131 away from the substrate 110 and the substrate 110 is a first distance, a distance between a surface of a side of each of the light-emitting units 141 away from the substrate 110 and the substrate 110 is a second distance, and the first distance is smaller than or equal to the second distance; and the orthographic projection of the light-shielding function layer 132 on each of the first electrode units 121 covers a part of the edge part 1211, and a minimum distance between the light-shielding function layer 132 and each of the pixel definition openings 1301 is larger than 0.

According to the display panel provided in the present disclosure, since the first distance is smaller than or equal to the second distance, a height of the surface of the side of the first pixel definition layer 131 away from the substrate 110 is not higher than a height of the surface of the side of each of the light-emitting units 141 away from the substrate 110. In the present disclosure, the orthographic projection of the light-shielding function layer 132 on the first electrode unit 121 covers the part of the edge part 1211, and the minimum distance between the light-shielding function layer 132 and each of the pixel definition openings 1301 is larger than 0, so as to ensure a certain safe distance reserved between the light-shielding function layer 132 disposed on the surface of the side of the first pixel definition layer 131 away from the substrate 110 and each of the light-emitting units 141, improve reliabilities of the light-emitting units 141, and further improve a use stability of the display panel.

In an embodiment, the edge part 1211 includes a first part 01 and a second part 02, an orthographic projection of the first part 01 on the substrate 110 overlaps an orthographic projection of the light-shielding function layer 132 on the substrate 110, an orthographic projection of the second part 02 on the substrate 110 does not overlap the orthographic projection of the light-shielding function layer 132 on the substrate 110, and a width W1 of the first part 01 is larger than or equal to a width W2 of the second part 02.

According to the display panel provided in the present disclosure, since the minimum distance between the light-shielding function layer 132 and each of the pixel definition openings 1301 is larger than 0, at least part of the edge part 1211 cannot be covered by the light-shielding function layer 132, in order to ensure the reliability of the light-emitting units 141 while also taking into account a shading effect of the light-shielding function layer 132 on the edge part 1211, the width W1 of the first part 01 is larger than or equal to the width W2 of the second part 02 in the present disclosure. That is, in a width direction of the edge part 1211, at least half of the edge part 1211 can be covered by the light-shielding function layer 132.

In some embodiments of the present disclosure, the pixel definition layer 130 further includes a transparent second pixel definition layer 133, the second pixel definition layer 133 is disposed on the surface of the side of the light-shielding function layer 132 away from the substrate 110, and an orthographic projection of the second pixel definition layer 133 on the light-shielding function layer 132 covers the light-shielding function layer 132.

According to the display panel provided in the present disclosure, since the surface of the side of the light-shielding function layer 132 away from the substrate 110 is provided with the transparent second pixel definition layer 133, and the orthographic projection of the second pixel definition layer 133 on the light-shielding function layer 132 covers the light-shielding function layer 132, the second pixel definition layer 133 and the first pixel definition layer 131 can cover the light-shielding function layer 132, the light-shielding function layer 132 is well isolated from the light-emitting units 141, and the reliabilities of the light-emitting units 141 are further improved.

In an embodiment, the second pixel definition layer 133 has various thicknesses, and the second pixel definition layer 133 with various thicknesses can be prepared by a halftone mask method. The second pixel definition layer 133 includes at least one protrusion part, and the protrusion part is a photo spacer (PS) in the display panel.

In some embodiments of the present disclosure, the light-shielding function layer 132 includes multiple light holes, and orthographic projections of the light filter units 191 on the light-shielding function layer 132 cover the light holes.

Specifically, the first pixel definition layer 131 includes multiple first pixel definition openings, the second pixel definition layer 133 includes multiple second pixel definition openings, the first pixel definition openings and the second pixel definition openings form the pixel definition openings 1301, the light-emitting units 141 in the pixel definition openings 1301 are configured to execute a light-emitting function, light emitted by the light-emitting units 141 passes through the light filter units 191 and exits outside the display panel. Orthographic projections of the first pixel definition openings and the second pixel definition openings on the light-shielding function layer 132 are located in the light holes, that is, areas of the light holes are larger than areas of the first pixel definition openings and the second pixel definition openings. But in the meantime, in order to ensure a light-emitting effect of the light-emitting units 141, and make the light filter units 191 receive more light emitted by the light-emitting units 141, orthographic projections of the light filter units 191 on the light-shielding function layer 132 should cover the light holes, that is, areas of the light filter units 191 are larger than the areas of the light holes.

In some embodiments of the present disclosure, the light filter units 191 include a red light filter unit, a blue light filter unit and a green light filter unit, and a transmittance of each of the light filter units 191 for light with a color corresponding to the light filter unit is larger than or equal to 43%.

Specifically, the transmittance of the light filter units 191 is directly proportional to anti-reflectivity of the light filter units 191, when the light filter units 191 are able to transmit more light of the corresponding color emitted by the light-emitting units 141, more corresponding colored light from external ambient light can also be emitted into an interior of the display panel through the light filter units 191, thus generating more reflected light, when the transmittance of each of the light filter units 191 for light with the color corresponding to the light filter unit 191 is larger than or equal to 43%, the reflected light generated by the external ambient light can have a significant effect on display quality of the display panel. Correspondingly, when the transmittance of each of the light filter units 191 for light with the color corresponding to the light filter unit is larger than or equal to 43%, the reflected light is correspondingly reduced or eliminated by disposing the light-shielding function layer 132 in the present disclosure, thereby ensuring a light-emitting efficiency of the display panel while improving the anti-reflective performance of the display panel, and avoiding the problem of the reflection generated in the off-screen state of the display panel.

In some embodiments of the present disclosure, the display panel further includes a second electrode layer 150, and the second electrode layer 150 is disposed on the side of the pixel definition layer 130 away from the substrate 110 by adopting a full-face disposing method. Specifically, the first electrode layer 120 is one of an anode layer and a cathode layer, and the second electrode layer 150 is another one of the anode layer and cathode layer.

In some embodiments of the present disclosure, the display panel further includes an encapsulation layer 160 disposed on a side of the second electrode layer 150 away from the substrate 110, and the encapsulation layer 160 includes a first encapsulation layer 161, a second encapsulation layer 162 and a third encapsulation layer 163, and the first encapsulation layer 161, the second encapsulation layer 162 and the third encapsulation layer 163 are sequentially stacked in a direction away from the substrate 110, the first encapsulation layer 161 and the third encapsulation layer 163 are inorganic encapsulation layers, and the second encapsulation layer 162 is an organic encapsulation layer.

In some embodiments of the present disclosure, the display panel further includes a touch function layer 170 disposed on a side of the encapsulation layer 160 away from the substrate 110, and the touch function layer 170 includes a first touch insulation layer 171, a first touch electrode layer 172, a second touch insulation layer 173 and a second touch electrode layer 174, and the first touch insulation layer 171, the first touch electrode layer 172, the second touch insulation layer 173 and the second touch electrode layer 174 are sequentially stacked in the direction away from the substrate 110. Furthermore, the first touch electrode layer 172 includes multiple first touch electrodes, the second touch electrode layer 174 includes multiple second touch electrodes, orthographic projections of the first touch electrodes and the second touch electrodes on the substrate 110 are covered by the orthographic projection of the light-shielding function layer 132 on the substrate 110, so as to eliminate internal reflected light of the display panel reflected by the first touch electrodes and the second touch electrodes by the light-shielding function layer 132.

In some embodiments of the present disclosure, the display panel further includes a black matrix 180, the black matrix 180 is disposed on a side of the touch function layer 170 away from the substrate 110, and defines multiple openings, and the light filter units 191 correspondingly fill the openings. An orthographic projection of the black matrix 180 on the substrate 110 covers the orthographic projections of the first touch electrodes and the second touch electrodes on the substrate 110.

In some embodiments of the present disclosure, the display panel further includes a passivation layer 200, an optical adhesive layer 210 and a protective layer 220, the passivation layer 200 is disposed on sides of the black matrix 180 and the light filter units 190 away from the substrate 110, the optical adhesive layer 210 is disposed on a side of the passivation layer 200 away from the substrate 110, and the protective layer 220 is disposed on a side of the optical adhesive layer 210 away from the substrate 110.

According to another aspect, the present disclosure further provides a display device, and the display device includes a housing and a display panel according to anyone of the above, and the housing has an accommodating space in which the display panel is disposed.

### Embodiment 2

FIG. 2 illustrates a schematic structural diagram of a display panel according to the embodiment 2 of the present disclosure. As shown in connection with FIG. 1 and FIG. 2, the embodiment 2 of the present disclosure provides a display panel, and the display panel includes a substrate 110, a first electrode layer 120, a pixel definition layer 130, a light-emitting layer 140 and a light filter layer 190, the first electrode layer 120 is disposed on a side of the substrate 110, and includes multiple first electrode units 121 arranged at intervals; the pixel definition layer 130 is disposed on a side of the first electrode layer 120 away from the substrate 110, and defines multiple pixel definition openings 1301, and the pixel definition openings 1301 are disposed correspondingly to the first electrode units 121; the light-emitting layer 140 is disposed on a side of the pixel definition layer 130 away from the substrate 110, and covers parts of the first electrode units 121 exposed by the pixel definition openings 1301; the light filter layer 190 is disposed on a side of the light-emitting layer 140 away from the substrate 110, and includes multiple light filter units 191, and the light filter units 191 are disposed correspondingly to the pixel definition openings 1301; and each of the first electrode units 121 includes an edge part 1211 protruded from an edge of the light-emitting units 141, the pixel definition layer 130 includes a light-shielding function layer 132, an orthographic projection of the light-shielding function layer 132 on each of the first electrode units 121 covers at least part of the edge part 1211, and the light-shielding function layer 132 and the light-emitting layer 140 are arranged at intervals.

It should be noted that a structure of the display panel provided in the embodiment 2 of the present disclosure is similar to the display panel provided in the embodiment 1 of the present disclosure, and this embodiment 2 will not repeat the same parts.

According to the display panel provided in the embodiment, the light-emitting layer 140 includes multiple light-emitting units 141, and the light-emitting units 141 are disposed in the pixel definition openings 1301; a distance between the surface of the side of the first pixel definition layer 131 away from the substrate 110 and the substrate 110 is a first distance, a distance between the surface of the side of each of the light-emitting units 141 away from the substrate 110 and the substrate 110 is a second distance, and the first distance is larger than the second distance; and the orthographic projection of the light-shielding function layer 132 on each of the first electrode units 121 covers the at least part of the edge part 1211, and a minimum distance between the light-shielding function layer 132 and each of the pixel definition openings 1301 is equal to 0.

Specifically, since the first distance is larger than the second distance, a height of the surface of the side of the first pixel definition layer 131 away from the substrate 110 is higher than a height of the surface of the side of each of the light-emitting units 141 away from the substrate 110, therefore, the light-shielding function layer 132 disposed on the surface of the side of the first pixel definition layer 131 away from the substrate 110 has already separated from the light-emitting units 141 through the first pixel definition layer 131, correspondingly, the minimum distance between the light-shielding function layer 132 and each of the pixel definition openings 1301 is equal to 0, that is, the light holes in the light-shielding function layer 132 also participate in a formation of the pixel definition openings 1301, such structure can make a setting area of the light-shielding function layer 132 maximum, thus increasing an overlapping area of the light-shielding function layer 132 and the edge part 1211, that is, increasing an area of the first part 01 in the edge part 1211, further improving the anti-reflective performance of the display panel, and improving the problem of the reflection generated in the off-screen state of the display panel. Specifically, the width W1 of the first part 01 is at least twice as large as the width W2 of the second part 02.

It should be noted that in the display panel shown in FIG. 2, the orthographic projection of the light-shielding function layer 132 on each of the first electrode units 121 covers a part of the edge part 1211, however, in other embodiments of the present disclosure, side walls of the pixel definition openings 1301 may be disposed perpendicular to the substrate 110, so that the orthographic projection of the light-shielding function layer 132 on each of the first electrode units 121 completely covers the edge part 1211, so as to maximize a shading area of the light-shielding function layer 132, and further improve the anti-reflective performance of the display panel.

According to another aspect, the present disclosure further provides a display device, and the display device includes a housing and a display panel according to anyone of the above, and the housing defines an accommodating space in which the display panel is disposed.

In summary, the present disclosure provides the display panel and the display device, the display panel includes the substrate, the first electrode layer, the pixel definition layer, the light-emitting layer and the light filter layer, the first electrode layer is disposed on the side of the substrate, and includes the first electrode units arranged at intervals; the pixel definition layer is disposed on the side of the first electrode layer away from the substrate, and defines the pixel definition openings, and the pixel definition openings are disposed correspondingly to the first electrode units; the light-emitting layer is disposed on the side of the pixel definition layer away from the substrate, and covers the parts of the first electrode units exposed by the pixel definition openings; the light filter layer is disposed on the side of the light-emitting layer away from the substrate, and includes the light filter units, and the light filter units are disposed correspondingly to the pixel definition openings; and each of the first electrode units includes the edge part protruded from the edge of each of the pixel definition openings, the pixel definition layer includes the light-shielding function layer, the orthographic projection of the light-shielding function layer on each of the first electrode units covers at least part of the edge part, and the light-shielding function layer and the light-emitting layer are arranged at intervals. According to the display panel and the display device provided by the present disclosure, since the pixel definition layer includes the light-shielding function layer, and the orthographic projection of the light-shielding function layer on the first electrode unit covers the at least part of the edge part, the pixel definition layer may absorb the reflected light generated by the external ambient light on the edge part, so as to effectively improve the anti-reflective performances of the display panel and the display device, and improve the problem of the reflection generated in the off-screen state of the display panel.

The above provides a detailed description to the display panel and the display device provided in the embodiments of the present disclosure, principles and implementation methods of the present disclosure are described by applying specific examples, and the above examples are only used to help understand the methods and core ideas of the present disclosure; meanwhile, for those skilled in the art, there may be changes in the specific implementation methods and application scope based on the ideas of the present disclosure. In summary, the content of the specification should not be understood as a limitation of the present disclosure.

What is claimed is:

1. A display panel, comprising:
a substrate;
a first electrode layer disposed on a side of the substrate and comprising a plurality of first electrode units arranged at intervals;
a pixel definition layer disposed on a side of the first electrode layer away from the substrate and defining a plurality of pixel definition openings corresponding to the plurality of first electrode units;
a light-emitting layer disposed on a side of the pixel definition layer away from the substrate and covering the plurality of first electrode units exposed by the plurality of pixel definition openings; and
a light filter layer disposed on a side of the light-emitting layer away from the substrate and comprising a plurality of light filter units corresponding to the plurality of pixel definition openings;
wherein each of the plurality of first electrode units comprises an edge part protruded from an edge of one of the plurality of pixel definition openings corresponding to the first electrode unit, the pixel definition layer comprises a light-shielding function layer, an orthographic projection of the light-shielding function layer on the first electrode unit covers at least a portion of the edge part, and the light-shielding function layer and the light-emitting layer are arranged at intervals.

2. The display panel according to claim 1, wherein
the pixel definition layer further comprises a transparent first pixel definition layer disposed on a surface of a side of the substrate facing towards the first electrode layer, wherein the light-shielding function layer is disposed on a surface of a side of the first pixel definition layer away from the substrate, and an orthographic projection of the first pixel definition layer on each of the plurality of first electrode units covers an edge part corresponding to the first electrode unit.

3. The display panel according to claim 2, wherein the surface of the side of the first pixel definition layer away from the substrate is a flat surface.

4. The display panel according to claim 3, wherein
the light-emitting layer comprises a plurality of light-emitting units respectively disposed in the plurality of pixel definition openings;
a distance between the surface of the side of the first pixel definition layer away from the substrate and the substrate is a first distance, a distance between a surface of a side of each of the plurality of light-emitting units away from the substrate and the substrate is a second distance, and the first distance is smaller than or equal to the second distance; and
an orthographic projection of the light-shielding function layer on each of the plurality of first electrode units covers a portion of the edge part corresponding to the first electrode unit, and a minimum distance between the light-shielding function layer and each of the plurality of pixel definition openings is larger than 0.

5. The display panel according to claim 4, wherein
the edge part comprises a first part and a second part, wherein an orthographic projection of the first part on the substrate overlaps an orthographic projection of the light-shielding function layer on the substrate, an orthographic projection of the second part on the substrate does not overlap the orthographic projection of the light-shielding function layer on the substrate, and a width of the first part is larger than or equal to a width of the second part.

6. The display panel according to claim 5, wherein
the pixel definition layer further comprises a transparent second pixel definition layer disposed on a surface of a side of the light-shielding function layer away from the substrate, wherein an orthographic projection of the second pixel definition layer on the light-shielding function layer covers the light-shielding function layer.

7. The display panel according to claim 3, wherein
the light-emitting layer comprises a plurality of light-emitting units respectively disposed in the plurality of pixel definition openings;
a distance between the surface of the side of the first pixel definition layer away from the substrate and the substrate is a first distance, a distance between a surface of a side of each of the plurality of light-emitting units away from the substrate and the substrate is a second distance, and the first distance is larger than the second distance; and
an orthographic projection of the light-shielding function layer on each of the plurality of first electrode units covers at least a portion of the edge part corresponding to the first electrode unit, and a minimum distance between the light-shielding function layer and each of the plurality of pixel definition openings is equal to 0.

8. The display panel according to claim 1, wherein the light-shielding function layer comprises a plurality of light holes, and an orthographic projection of each of the plurality of light filter units on the light-shielding function layer cover respective one of the plurality of light holes.

9. The display panel according to claim 1, wherein the plurality of light filter units comprise a red light filter unit, a blue light filter unit, and a green light filter unit, and a transmittance of each of the plurality of light filter units for light with a color corresponding to the light filter unit is larger than or equal to 43%.

10. The display panel according to claim 1, wherein
the display panel further comprises a touch function layer disposed on a side of the pixel definition layer away from the substrate, wherein the touch function layer comprises a plurality of first touch electrodes and a plurality of second touch electrodes, and orthographic projections of the plurality of first touch electrodes and the plurality of second touch electrodes on the substrate are covered by an orthographic projection of the light-shielding function layer on the substrate.

11. A display device, comprising a housing and a display panel, wherein the housing defines an accommodating space, the display panel is disposed in the accommodating space, and the display panel comprises:
a substrate;
a first electrode layer disposed on a side of the substrate and comprising a plurality of first electrode units arranged at intervals;
a pixel definition layer disposed on a side of the first electrode layer away from the substrate and defining a plurality of pixel definition openings corresponding to the plurality of first electrode units;
a light-emitting layer disposed on a side of the pixel definition layer away from the substrate and covering the plurality of first electrode units exposed by the plurality of pixel definition openings; and
a light filter layer disposed on a side of the light-emitting layer away from the substrate and comprising a plurality of light filter units corresponding to the plurality of pixel definition openings;
wherein each of the plurality of first electrode units comprises an edge part protruded from an edge of one of the plurality of pixel definition openings corresponding to the first electrode unit, the pixel definition layer comprises a light-shielding function layer, an orthographic projection of the light-shielding function layer on the first electrode unit covers at least a portion of the edge part, and the light-shielding function layer and the light-emitting layer are arranged at intervals.

12. The display device according to claim 11, wherein
the pixel definition layer further comprises a transparent first pixel definition layer disposed on a surface of a side of the substrate facing towards the first electrode layer, wherein the light-shielding function layer is disposed on a surface of a side of the first pixel definition layer away from the substrate, and an orthographic projection of the first pixel definition layer on each of the plurality of first electrode units covers an edge part corresponding to the first electrode unit.

13. The display device according to claim 12, wherein the surface of the side of the first pixel definition layer away from the substrate is a flat surface.

14. The display device according to claim 13, wherein
the light-emitting layer comprises a plurality of light-emitting units respectively disposed in the plurality of pixel definition openings;
a distance between the surface of the side of the first pixel definition layer away from the substrate and the substrate is a first distance, a distance between a surface of a side of each of the plurality of light-emitting units away from the substrate and the substrate is a second distance, and the first distance is smaller than or equal to the second distance; and
an orthographic projection of the light-shielding function layer on each of the plurality of first electrode units covers a portion of the edge part corresponding to the first electrode unit, and a minimum distance between the light-shielding function layer and each of the plurality of pixel definition openings is larger than 0.

15. The display device according to claim 14, wherein
the edge part comprises a first part and a second part, wherein an orthographic projection of the first part on the substrate overlaps an orthographic projection of the light-shielding function layer on the substrate, an orthographic projection of the second part on the substrate does not overlap the orthographic projection of the light-shielding function layer on the substrate, and a width of the first part is larger than or equal to a width of the second part.

16. The display device according to claim 15, wherein
the pixel definition layer further comprises a transparent second pixel definition layer disposed on a surface of a side of the light-shielding function layer away from the substrate, wherein an orthographic projection of the second pixel definition layer on the light-shielding function layer covers the light-shielding function layer.

17. The display device according to claim 13, wherein
the light-emitting layer comprises a plurality of light-emitting units respectively disposed in the plurality of pixel definition openings;
a distance between the surface of the side of the first pixel definition layer away from the substrate and the substrate is a first distance, a distance between a surface of a side of each of the plurality of light-emitting units away from the substrate and the substrate is a second distance, and the first distance is larger than the second distance; and
an orthographic projection of the light-shielding function layer on each of the plurality of first electrode units covers at least a portion of the edge part corresponding to the first electrode unit, and a minimum distance between the light-shielding function layer and each of the plurality of pixel definition openings is equal to 0.

18. The display device according to claim 11, wherein the light-shielding function layer comprises a plurality of light holes, and an orthographic projection of each of the plurality of light filter units on the light-shielding function layer cover respective one of the plurality of light holes.

19. The display device according to claim 11, wherein the plurality of light filter units comprise a red light filter unit, a blue light filter unit, and a green light filter unit, and a transmittance of each of the plurality of light filter units for light with a color corresponding to the light filter unit is larger than or equal to 43%.

20. The display device according to claim 11, wherein
the display panel further comprises a touch function layer disposed on a side of the pixel definition layer away from the substrate, wherein the touch function layer comprises a plurality of first touch electrodes and a plurality of second touch electrodes, and orthographic projections of the plurality of first touch electrodes and the plurality of second touch electrodes on the substrate are covered by an orthographic projection of the light-shielding function layer on the substrate.
